(19) United States
(12) Patent Application Publication
(10) Pub. No.: US 2005/0227654 A1
(43) Pub. Date: Oct. 13, 2005

(54) Method of communication channel estimation and information receiving terminal using the same

(75) Inventor: Che-Li Lin, Taipei City (TW)

Correspondence Address: SNELL & WILMER;ONE ARIZONA CENTER, 400 EAST VAN BUREN, PHOENIX, AZ, 850040001, US

(73) Assignee: BENQ CORPORATION

(21) Appl. No.: 11/095,692

(22) Filed: Apr. 1, 2005

(30) Foreign Application Priority Data
Apr. 7, 2004 (TW) 93109593

(51) Int. Cl. H04B 17/00; H04B 1/00; H03K 3/02

(52) U.S. Cl. 455/226.1; 455/140; 455/67.11

(57) ABSTRACT

A method of communication channel estimation between a transmitter and a receiver is provided. The method includes the step (a): receiving at a first interval a first signal transmitted by the transmitter and obtaining a first channel characteristic corresponding to the first signal; (b): receiving at a second interval a second signal transmitted by the transmitter and obtaining a second channel characteristic corresponding to the second signal; (c) obtaining a value based on the first channel characteristic and the second channel characteristic; and (d) selecting the second channel characteristic or an estimated channel characteristic based on the value.

### CROSS-REFERENCE TO RELATED APPLICATIONS

This application claims the right of priority based on Taiwan Patent Application No. 093109593 entitled “Communication Channel Characteristic Estimation Method,” filed on Apr. 07, 2004, which is incorporated herein by reference and assigned to the assignee herein.

### FIELD OF INVENTION

The present invention relates to a method of communication channel estimation and an information receiving terminal. More specifically, it relates to a method of communication channel estimation for a wireless communication system and a communication terminal operable in the wireless communication system.

### BACKGROUND OF THE INVENTION

In a general communication system, a signal is transmitted via a channel between a transmitter and a receiver. During the propagation of the signal, the signal may be distorted because of fading, interference, etc. Channel estimation is the estimate of the distortion, between the transmitter and the receiver of a signal, introduced by the physical channel or medium through which the signal was transmitted. Using an estimate of this distortion, the receiver obtains the channel characteristic and compensates the distortion.

Typically, a communication channel allows multiple path signals. When transmitted via those multiple path signals, each signal has one “time of arrival (TOA)” and one Doppler frequency for each path. The receiver performs the channel estimation to determine TOA, Doppler frequency, and corresponding gain for each path. Particularly for a mobile phone communication system, the channel characteristic fluctuates when the mobile station is moving. Thus real-time channel estimations have been widely adopted.

FIG. 1 is an illustration of a mobile phone communication system according to the prior art. The mobile phone communication system includes a transmitter 110 and a receiver 130. The receiver 130 includes a channel estimator 132 and a data compensator 134. A signal is transmitted via the channel 120 between the transmitter 110 and the receiver 130. The data signal may include a training sequence, which is a predetermined data format already known to both the transmitter 110 and the receiver 130. The training sequence is predetermined as TS1(t) at the transmitter 110, and the receiver 130 receives the training sequence as TS2(t). TS2(t) is equal to “TS1(t)·h1(t)”, wherein h1(t) represents distortions along the channel 120. Accordingly, the channel estimator 132 obtains a channel characteristic h2(t) based on h1(t), and the data compensator 134 compensates the distorted, received signal according to the h2(t). However, when h1(t) fluctuates too seriously, for example, because the receiver 130 moves at high speed, h2(t) derived from h1(t) is inappropriate for the data compensator 134.

### SUMMARY OF THE INVENTION

The main aspect of the present invention provides a method of communication channel estimation and an information receiving terminal using the method.

Another aspect of the present invention provides, for a wireless communication system, a method of communication channel estimation and a communication terminal using the method.

Still another aspect of the present invention provides, for a TDMA (Time Division Multiple Access) communication system, a method of communication channel estimation and a communication terminal using the method.

In one embodiment, a method of communication channel estimation between a transmitter and a receiver is provided. The method includes the step (a): receiving at a first interval a first signal transmitted by the transmitter and obtaining a first channel characteristic corresponding to the first signal. The first channel characteristic may be obtained based on the first signal and a signal received at a predetermined interval prior to the first interval. The method also includes the step (b): receiving at a second interval a second signal transmitted by the transmitter and obtaining a second channel characteristic corresponding to the second signal. The second channel characteristic may be obtained based on the second signal and a signal received at a predetermined interval prior to the first interval. The step (c) is to obtain a value based on the first channel characteristic and the second channel characteristic. Next the step (d) is to select the second channel characteristic or an estimated channel characteristic based on the value. The length of each interval depends on the required accuracy, that is, shorter intervals are provided for higher accuracy. The second interval may longer than the first interval.

In another embodiment, a method of communication channel estimation for a “frequency hopping” communication system is provided. When the first signal and the second signal are transmitted via a first frequency channel (e.g., 900 MHz), the value in step (c) mentioned above is obtained as X1. And a step (d) is to select the second channel characteristic or the estimated channel characteristic based on X1. Likewise, when the first signal and the second signal are transmitted via a second frequency channel (e.g., 1800 MHz), the value in step (c) is obtained as X2. A step (d) is to select the second channel characteristic or the estimated channel characteristic based on X2.

The first channel characteristic and the second channel characteristic can be obtained according to the prior art, but they are regarded as “initial” channel characteristics in the present invention. The present invention discloses a value to represent the level of similarity between the first channel characteristic and the second channel characteristic. When the value indicates that the level of similarity is high, representative of those “initial” channel characteristics being similar to each other, the first channel characteristic and second channel characteristic provide reliable information to the receiver to compensate the distorted, received data signal. On the contrary, when the value indicates that the level of similarity is low, representative of those “initial” channel characteristics being apparently different from each other, the information provided by them is regarded as being unsuitable to the receiver to compensate the received data signal. In one embodiment for this situation, the receiver takes only the second channel characteristic for the channel estimation and neglects the first channel characteristic.

The present invention also provides an information receiving terminal. The information receiving terminal is operable in a communication system and communicates with an information transmitting terminal. The information receiving terminal is provided for performing the method mentioned above.

The foregoing and other features of the invention will be apparent from the following more particular description of embodiment of the invention.

### BRIEF DESCRIPTION OF THE DRAWINGS

The present invention is illustrated by way of example and not intended to be limited by the figures of the accompanying drawing, in which like notations indicate similar elements.

FIG. 1 is an illustration of a mobile phone communication system according to the prior art;

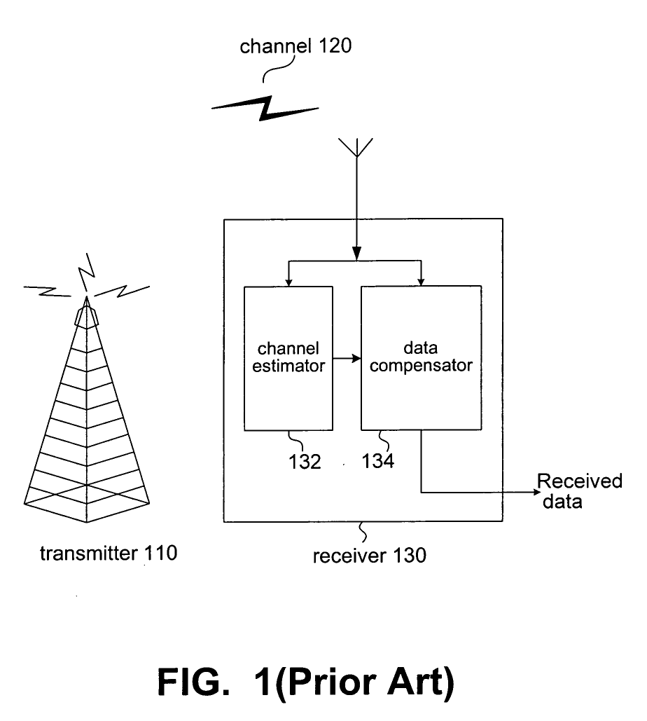

FIG. 2 is an illustration of an information receiving terminal operable in a wireless communication system according to an embodiment of the present invention; and

FIG. 3 is a flowchart of a method according to an embodiment of the present invention.

### DETAILED DESCRIPTION

The present invention is directed to a method of communication channel estimation. Preferably, the method is implemented in a base station or a mobile station of a TDMA (Time Division Multiple Access) communication system. It is known to those skilled in the art that the base station or the mobile station can include typical communication components, such as processor, coder, decoder, modulator, mixer, filter, antenna, waveguide, etc., and other hardware or software for operating those communication components. It should be noted that, for the purpose of understanding the present invention, the embodiments of the information receiving terminal is described first, which is followed by the embodiments of the method of communication channel estimation.

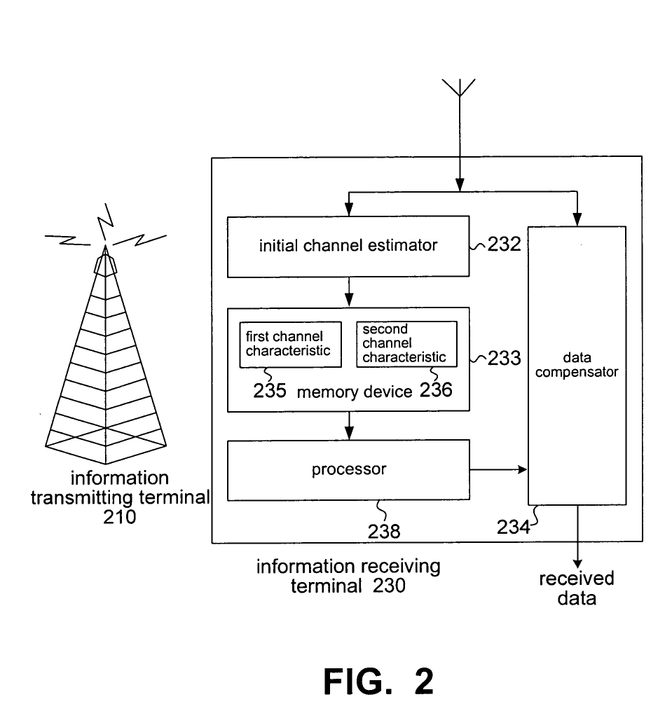

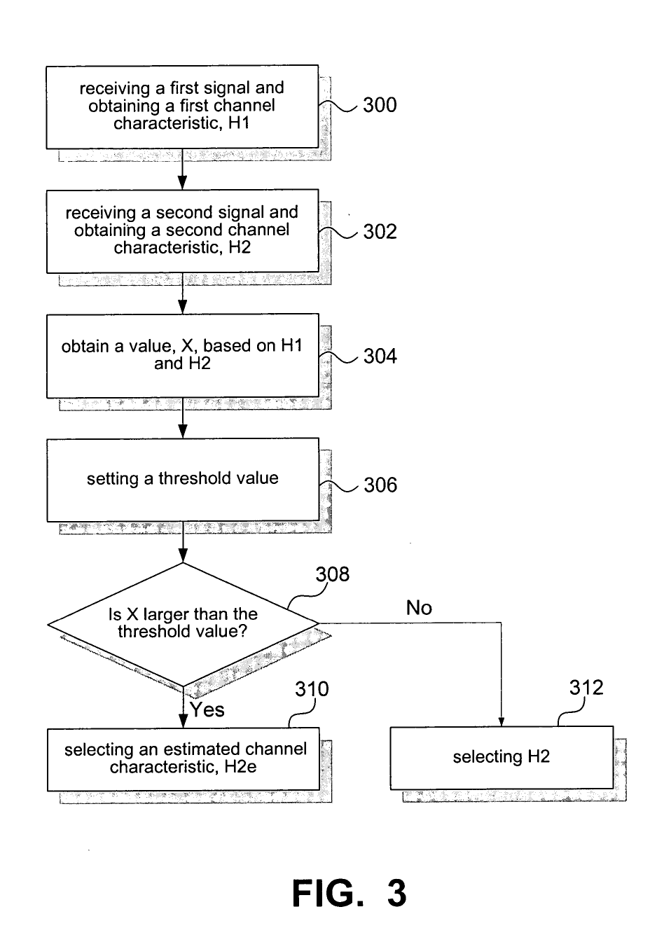

Referring to FIG. 2, the information receiving terminal 230 communicates with the information transmitting terminal 210 in a wireless communication system. The information receiving terminal 230 includes an initial channel estimator 232, a memory device 233, a data compensator 234, and a processor 238. The initial channel estimator 232 receives at a first interval a first signal transmitted by the information transmitting terminal 210 and obtains a first channel characteristic 235. Then the initial channel estimator 232 receives at a second interval a second signal transmitted by the information transmitting terminal 210 and obtains a second channel characteristic 236. The memory device 233 is provided for storing the first channel characteristic 235 and the second channel characteristic 236. The processor 238 calculates an estimated channel characteristic and performs the method depicted in FIG. 3 to select an appropriate channel characteristic. The data compensator 234 uses the selected channel characteristic to compensate the distortion of signals received from the information transmitting terminal 210. In an embodiment, the wireless communication system is a mobile phone communication system, and the information receiving terminal 230 is a mobile phone or a base station. In order to deal with the signals, the information receiving terminal 230 may include a digital signal processing (DSP) chip and an application-specific integrated circuit (ASIC). Furthermore, the processor 238 can execute specific software to function as described above.

FIG. 3 is a flowchart of a method of communication channel estimation between a transmitter and a receiver according to an embodiment of the present invention. It begins with the step 300 receiving at a first interval a first signal transmitted by the transmitter and obtaining a first channel characteristic, H1, corresponding to the first signal. In one embodiment, the first signal includes a training sequence, and H1 is obtained according to the procedure described in U.S. Pat. No. 6,542,560. Next it turns to the step 302 receiving at a second interval a second signal transmitted by the transmitter and obtaining a second channel characteristic, H2, corresponding to the second signal. In the embodiment, H2 is obtained by the way similar to H1 in the step 300. In another embodiment, the first signal and the second signal are respectively transmitted via n paths. Thus H1 is a sequence of h_{1,i}, and h_{1,i} represents a channel characteristic obtained when the first signal is transmitted through the i th path. Likewise, H2 is a sequence of h_{2,i}, and h_{2,i} represents a channel characteristic obtained when the second signal is transmitted through the i th path. In addition, it should be noted that, for a TDMA communication system, the length of the first interval or the second interval is equal to a timeslot or a regular time interval (typically including 8 timeslots).

The step 304 is to obtain a value, X, based on H1 in the step 300 and H2 in the step 302. In one embodiment, X is determined by: X=[(dot(H1,H2))]/[(|H1|·|H2 |)], wherein dot(H1,H2) represents the inner product of H1 and H2, and |H1| and |H2| represent respectively the absolute value of H1 and of H2. In another embodiment, the first signal and the second signal are respectively transmitted via n paths. H1 is a sequence of h_{1,i}, and H2 is a sequence of h_{2,i}. X is determined by:

$$X = \frac{{\sum }_{i = 1}^{n} dot ( H1 , H2 )}{{\sum }_{i = 1}^{n} \vert H1 \vert \cdot \vert H2 \vert} .$$

Ranging from 0 to 1, X represents the level of similarity between H1 and H2. When X is close to 1, H1 and H2 are similar to each other. On the contrary, when X is close to 0, H1 and H2 are dissimilar to each other.

Then the method goes to the step 306 setting a threshold value. In step 308, when X is larger than the threshold value, i.e., H1 and H2 are deemed to be similar to each other, it turns to the step 310 selecting an estimated channel characteristic, H2e. The receiver uses H2e to compensate the distortion of signals received from the transmitter. In one embodiment, H2e is determined by: H2e=(a·exp(j·angle(X))·H1+(1−a)·|X|·H2)/((a+(1−a)·|X|), wherein j is an imaginary unit, a is a real number between 0 and 1, and angle(X) represents a phase angle of X. When X is not larger than the threshold value in the step 308, i.e., H1 and H2 are deemed to be dissimilar to each other, it turns to the step 312 selecting H2 to compensate the distortion of signals.

In addition, the transmitter and the receiver can communicate via several RF channels, i.e., frequency-hopping. Those skilled in the art should know that different frequency channels result in different H1 and H2. In the step 304, when the first signal and the second signal are transmitted via a first frequency channel (e.g., 900 MHz), the value of X is equal to X1, and when the first signal and the second signal are transmitted via a second frequency channel (e.g., 1800 MHz), the value of X is equal to X2. In the following steps 306-312, when signals are transmitted via the first frequency channel, X1 is taken to select H2 or H2e. Likewise, when signals are transmitted via the second frequency channel, X2 is taken to select H2 or H2e.

While this invention has been described with reference to the illustrative embodiments, these descriptions should not be construed in a limiting sense. Various modifications of the illustrative embodiments, as well as other embodiments of the invention, will be apparent upon reference to these descriptions. It is therefore contemplated that the appended claims will cover any such modifications or embodiments as falling within the true scope of the invention and its legal equivalents.

1. A method for estimating a communication channel between a transmitter and a receiver, said method comprising:
(a) receiving a first signal transmitted by said transmitter during a first interval and obtaining a first channel characteristic, H1, corresponding to said first signal;
(b) receiving a second signal transmitted by said transmitter during a second interval and obtaining a second channel characteristic, H2, corresponding to said second signal;
(c) obtaining a value, X, based on said first channel characteristic, H1, and said second channel characteristic, H2; and
(d) selecting said second channel characteristic, H2, or an estimated channel characteristic, H2e, based on said value, X.

2. The method of claim 1, wherein said estimated channel characteristic, H2e, is determined by:
H2e=(a·exp(j·angle(X))·H1+(1−a)·|X |·H2)/((a+(1−a)·|X |), wherein j is an imaginary unit, a is a real number between 0 and 1, and angle(X) represents a phase angle of X.

3. The method of claim 2, wherein said value, X, is determined by:
X=[(dot(H1,H2))]/[(|H1|H2 |)], wherein dot(H1,H2) represents the inner product of H1 and H2.

4. The method of claim 2, wherein said first signal and said second signal are respectively transmitted via n paths;
wherein said first channel characteristic, H1, is a sequence of h_{1,i}, and h_{1,i} represents a channel characteristic obtained when said first signal is transmitted through the i th path;
wherein said second channel characteristic, H2, is a sequence of h_{2,i}, and h_{2,i} represents a channel characteristic obtained when said second signal is transmitted through the i th path; and
wherein said value, X, is determined by:
$$X = \frac{{\sum }_{i = 1}^{n} dot ( H1 , H2 )}{{\sum }_{i = 1}^{n} \vert H1 \vert \cdot \vert H2 \vert} .$$

5. The method of claim 1, wherein the step (d) further comprises:
(e) setting a threshold value; and
(f) selecting said estimated channel characteristic, H2e, when said value, X, is larger than said threshold value, or selecting said second channel characteristic, H2, when said value, X, is less than said threshold value.

6. The method of claim 1, wherein said first signal and said second signal are training sequences transmitted by said transmitter.

7. The method of claim 1, wherein the step (c) further comprises:
(g) X=X1 when said first signal and said second signal are transmitted via a first frequency channel; and
(h) X=X2 when said first signal and said second signal are transmitted via a second frequency channel.

8. The method of claim 1, wherein the step (a) further comprises:
obtaining said first channel characteristic, H1, based on said first signal and a signal received at a predetermined interval prior to said first interval.

9. The method of claim 1, wherein the step (b) further comprises:
obtaining said second channel characteristic, H2, based on said second signal and a signal received at a predetermined interval prior to said second interval.

10. An information receiving terminal, operable in a communication system, for communicating with an information transmitting terminal, said information receiving terminal performing the method of claim 1, said information receiving terminal comprising:
an estimation module for obtaining said first channel characteristic, H1, and said channel characteristic, H2;
a memory for storing said first channel characteristic, H1, and said channel characteristic, H2; and
a processor for calculating said value, X, and selecting said second channel characteristic H2, or said estimated channel characteristic, H2e, based on said value, X.

11. The information receiving terminal of claim 10, wherein said estimated channel characteristic, H2e, is determined by:
H2e=(a·exp(j·angle(X))·H1+(1−a)·|X |·H2)/((a+(1−a)·|X |), wherein j is an imaginary unit, a is a real number between 0 and 1, and angle(X) represents a phase angle of X.

12. The information receiving terminal of claim 11, wherein said value, X, is determined by:
X=[(dot(H1,H2))]/[(|H1|·|H2|)], wherein dot(H1,H2) represents the inner product of H1 and H2.

13. The information receiving terminal of claim 11, wherein said first signal and said second signal are respectively transmitted via n paths;
wherein said first channel characteristic, H1, is a sequence of h_{1,i}, and h_{1,i} represents a channel characteristic obtained when said first signal is transmitted through the i th path;
wherein said second channel characteristic, H2, is a sequence of h_{2,i}, and h_{2,i} represents a channel characteristic obtained when said second signal is transmitted through the i th path; and
wherein said value, X, is determined by:
$$X = \frac{{\sum }_{i = 1}^{n} dot ( H1 , H2 )}{{\sum }_{i = 1}^{n} \vert H1 \vert \cdot \vert H2 \vert} .$$

14. The information receiving terminal of claim 10, wherein the step (d) further comprises:
(e) setting a threshold value; and
(f) selecting said estimated channel characteristic, H2e, when said value, X, is larger than said threshold value, selecting said second channel characteristic, H2, when said value, X, is less than said threshold value.

15. The information receiving terminal of claim 10, wherein said first signal and said second signal are training sequences transmitted by said information transmitting terminal.

16. The information receiving terminal of claim 10, wherein the step (c) further comprises:
(g) X=X1 when said first signal and said second signal are transmitted via a first frequency channel; and
(h) X=X2 when said first signal and said second signal are transmitted via a second frequency channel.

17. The information receiving terminal of claim 10, wherein the step (a) further comprises:
estimating said first channel characteristic, H1, based on said first signal and a signal received at a predetermined interval prior to said first interval.

18. The information receiving terminal of claim 10, wherein the step (b) further comprises:
estimating said second channel characteristic, H2, based on said second signal and a signal received at a predetermined interval prior to said second interval.

19. The information receiving terminal of claim 10, wherein said communication system is a mobile phone communication system.

20. The information receiving terminal of claim 19, wherein said information receiving terminal is a mobile phone.
